(19) United States
(12) Patent Application Publication
(10) Pub. No.: US 2010/0154887 A1
(43) Pub. Date: Jun. 24, 2010

(54) PHOTOVOLTAIC SYSTEM

(76) Inventors: M. JAMES BULLEN, Los Gatos, CA (US); Dennis J. Huber, Great Falls, VA (US)

Correspondence Address: HAYNES AND BOONE, LLP;IP Section, 2323 Victory Avenue, Suite 700, Dallas, TX, 75219, US

(21) Appl. No.: 12/340,500

(22) Filed: Dec. 19, 2008

(51) Int. Cl. H01L 31/04; H01L 31/18

(52) U.S. Cl. 136/259; 438/25

(57) ABSTRACT

A photovoltaic system that includes a base; a photovoltaic material having an active area mounted to the base; and a protective covering mounted in the base and covering the photovoltaic material, the protective covering having a surface area larger than that of the active area and including an enhancement is presented. In some embodiments, the enhancement can include a lens area. In some embodiments, the enhancement can include a display area. Some embodiments further include a reflective layer between the protective covering and the photovoltaic material.

### BACKGROUND

1. Field of the Invention

The present invention relates to photovoltaic systems and, in particular, to a covered photovoltaic system that may be used in consumer electronics.

2. Discussion of Related Art

Photovoltaic systems convert light incident on a solar cell into electricity. In a concentrator system, light is focused onto the solar cell utilizing a mirror or lens. Concentrating light onto the solar cell can reduce the size of the solar cell for collection of a given area of incident light and therefore may reduce costs. Concentrator systems focus sunlight with a lens such as a conventional or Fresnel lens or a metal reflector onto solar cells. The solar cells convert light that is incident on the active area into electrical current.

Current embodiments of concentrator systems use a Fresnel lens or metal reflector to focus sunlight onto photovoltaic material. These systems tend to be large and bulky and are therefore not suitable for utilization in small portable solar systems such as those that would be useful with consumer electronics.

Therefore, there is a need for photovoltaic systems that are applicable to smaller, portable consumer electronics applications.

### SUMMARY

Consistent with the present invention, an apparatus includes a base; a photovoltaic material having an active area mounted to the base; and a protective covering mounted in the base and covering the photovoltaic material, the protective covering having a surface area larger than that of the active area and including an enhancement. In some embodiments, the enhancement can include a lens area. In some embodiments, the enhancement can include a display area. Some embodiments further include a reflective layer between the protective covering and the photovoltaic material.

These and other embodiments are further discussed below with reference to the following figures.

### BRIEF DESCRIPTION OF THE DRAWINGS

FIG. 1 shows a cross-sectional view of a conventional photovoltaic system.

FIG. 2 shows a planar view of a photovoltaic system consistent with some embodiments of the present invention.

FIG. 3 shows planar view of another photovoltaic system consistent with some embodiments of the present invention.

FIG. 4 shows a cross-sectional view of the photovoltaic system illustrated in FIG. 3.

FIG. 5 shows a cross-sectional view of the photovoltaic system shown in FIGS. 2 and 3.

FIG. 6 illustrates the ability of a lens as shown in FIG. 5 to concentrate light consistent with some embodiments of the present invention.

FIG. 7 shows a cross sectional view of some embodiments of a photovoltaic system consistent with the present invention.

FIG. 8 illustrates selective reflection of certain wavelengths in some embodiments of a photovoltaic system as shown in FIG. 7.

FIG. 9 shows a photograph of an embodiment of photovoltaic system consistent with the present invention.

FIG. 10 shows a cross sectional view of some embodiments of a photovoltaic system consistent with the present invention.

FIGS. 11A and 11B compare a Fresnel lens to a normal lens.

FIGS. 12A, 12B, and 12C illustrate a particular embodiment of photovoltaic system consistent with the present invention.

In the figures, elements having the same or similar functions have the same designation.

### DETAILED DESCRIPTION

Certain embodiments of a photovoltaic system are described below. Some embodiments of the photovoltaic system may be helpful in the promotion of products in the consumer electronics marketplace. Unlike the commercial marketplace where solar systems are utilitarian, the consumer marketplace can place fashion or style ahead of functionality or performance. In the consumer marketplace, a sleek design may mean more than a better performing, but less pleasing design. Further, photovoltaic systems suitable for the consumer market should be small and portable while producing enough power to, for example, charge a battery in a connected device.

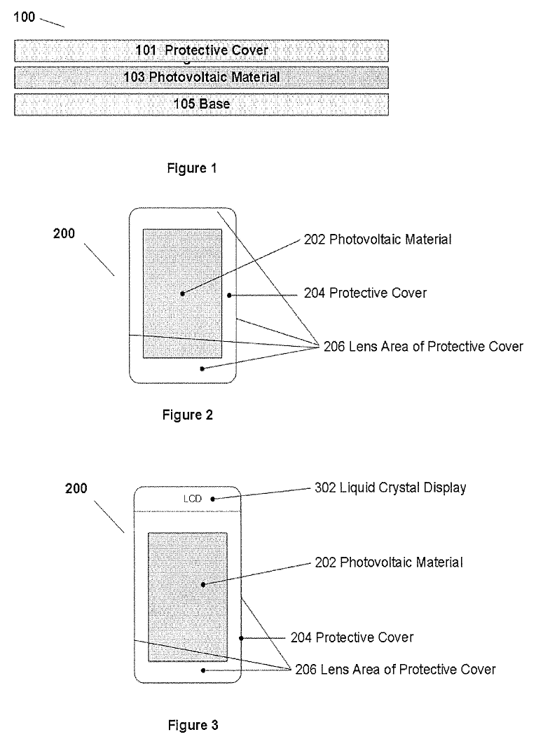

FIG. 1 illustrates a cross section of a conventional photovoltaic system 100. Photovoltaic system 100 includes a photovoltaic material 103 on a base 105 that is covered by a protective cover 101. Protective cover 101 protects photovoltaic material 103 while allowing light, usually sunlight, incident on photovoltaic system 100 to pass to photovoltaic material 103. Protective cover 101 may have a very high transmittance (usually glass) to protect photovoltaic material 103 and provide light to photovoltaic material 103. Protective cover 101 often includes an anti-reflective material applied over photovoltaic material 103, which is typically composed of silicon or gallium arsenide. Photovoltaic material 103 is applied to a base 105, which is typically a strong, light weight frame composed of material such as aluminum.

In a conventional consumer application, concentration of light onto photovoltaic material 103 is accomplished by optical systems arranged outside of photovoltaic system 100. Photovoltaic material 103, which usually includes multiple photovoltaic cells, is the most expensive component of photovoltaic system 100, on a per-area basis. A concentrator makes use of relatively inexpensive materials such as plastic lenses and metal housings to capture the solar energy shining on an area and focus that energy onto a smaller area, where photovoltaic material 103 is located, where that light is converted into electricity. Concentrating sunlight to reduce the size of solar cells reduces costs. Such systems focus sunlight onto solar cells, which may be high efficiency gallium arsenide (GaAs) cells, for example, or more conventional silicon based or thin-film cells. GaAs solar cells are typically about twice as efficient as conventional silicon cells.

Current embodiments of concentrator systems may utilize lenses such as Fresnel lenses or metal reflectors positioned outside of, and separate from, photovoltaic system 100 to focus sunlight onto an area of photovoltaic material 103 of photovoltaic system 100. As a result, a concentrator system utilizing photovoltaic system 100 may be large and bulky and may not be appropriate for applications in smaller, portable systems such as in consumer electronics systems like cell phones, computers, or other devices.

FIG. 2 illustrates a planar view of some embodiments of photovoltaic system 200 consistent with the present invention. In the embodiment shown in FIG. 2, photovoltaic system 200 includes a protective cover 204 to protect a photovoltaic material 202. Photovoltaic material 202 has a surface area smaller than that of protective cover 204. In the embodiment shown in FIG. 2, protective cover 204 includes an enhancement that includes a lens area 206 to concentrate light incident on protective cover 204 onto the smaller surface area of photovoltaic material 202.

As shown in FIG. 2, a portion of protective cover 204 includes a lens area 206 to direct light from the edges of protective cover 204, or other areas as appropriate, onto the active surface of photovoltaic material 202. Increasing the intensity of light on the photovoltaic material increases the energy production of the photovoltaic system. Additionally, protective covering 204 may have an index of refraction that maximizes the potential for internal reflection, thereby further increasing the intensity of light incident on the photovoltaic material and increasing the power production of photovoltaic system 200. Protective cover 204 can be arranged to have good transmittance properties, internal reflection, and concentration properties.

In optics and spectroscopy, transmittance is the fraction of incident light at a specified wavelength that passes through a sample. The transmittance T through a material is defined by

T=I₁/I₀,

where I₀ is the intensity of light incident on the material and I₁ is the intensity of light that exits the material. The transmittance of a sample is sometimes given as a percentage. Transmittance is related to absorbance A, which is a measure of the amount of light being absorbed by the material, through the Beer-Lambert law.

The Beer-Lambert law states that there is a logarithmic dependence between the transmittance of light through the material and the product of the absorption coefficient of the material and the distance l that the light travels through material (i.e. the path length). From the Beer-Lambert law,

A=αl=−In T=−ln(I₁/I₀)

From the above equation, the transmittance through the material is given by

T=e^{-αl},

where α is the attenuation coefficient of the material and l is the path length through the material. The transmittance of protective cover 202 as shown in FIG. 2 determines the intensity of incident light on photovoltaic material 204. The more light that is not transmitted at wavelengths important to the photovoltaic process, the less efficient the overall system becomes at producing electricity from the incident light.

Another factor that may affect the efficiency of photovoltaic system 200 is the amount of internal reflection that can be generated. Total internal reflection is an optical phenomenon that occurs when a ray of light strikes a medium boundary at an angle larger than the critical angle with respect to the normal to the surface. If the refractive index is lower on the other side of the boundary no light can pass through, so effectively all of the light is reflected. The critical angle θ_{c} is the angle of incidence above which total internal reflection occurs, i.e. all of the light incident on the material is reflected from the boundary.

When light crosses a boundary a material of refractive index n₁ to a material with refractive index n₂, the light beam will be partially refracted at the boundary, and partially reflected. However, if the angle of incidence is greater (i.e. the ray is closer to being parallel to the boundary) than the critical angle θ_{c}—the angle of incidence at which light is refracted such that it travels along the boundary—then the light will stop crossing the boundary altogether and instead be totally reflected. This can only occur where light travels from a medium with a higher refractive index to one with a lower refractive index (n₁>n₂). For example, it will occur when passing from glass to air, but not when passing from air to glass.

This physical property makes optical fibers useful, and rainbows and prismatic binoculars possible. It is also what gives diamonds their distinctive sparkle, as diamond has an extremely high refractive index. The critical angle θ_{c} can be determined from Snell's law.

Snell's law is used to describe the relationship between the angle of incidence and the angle of refraction for light passing through a boundary between two different isotropic media. Snell's law says that the ratio of the sine of the angles of incidence and of refraction is a constant that depends on the media. In particular, Snell's law states that the ratio of the sine's of the angle of incidence θ₁ and the angle of refraction θ₂ is equivalent to the ratio of velocities in the two media, or equivalent to the opposite ratio of the indices of refraction:

(n2/n1)=(sin θ₁/sin θ₂).

In the case where n₁>n₂, because the velocity is lower in the first medium than in the second medium (v₁<v₂), the angle of refraction θ₂ is less than the angle of incidence θ₁; that is, a ray in the higher-index medium is closer to the normal than is a ray in the lower-index medium.

If the incident ray is precisely at the critical angle, the refracted ray is tangent to boundary 1310 at the point of incidence, or θ₂=90° so that the sin θ₂=1. The critical angle θ_{c} is given by:

θ_{c}=arc sin(n₂/n₁),

where n₂ is the refractive index of the less dense medium, n₁ is the refractive index of the denser medium.

If for example, visible light were traveling from a glass (e.g., Lucite with an index of refraction of 1.50) into air (with an index of refraction of 1.00), the critical angle θ_{c} is given by

θ_{c}=arc sin(1.00/1.5)=41.8.

If the angle of the light were at the critical angle θ_{c} then the refracted beam would be on the border of the glass-air interface. If the fraction n₂/n₁ is greater than 1, then arcsine is not defined, meaning that total internal reflection does not occur even at very shallow or grazing incident angles. Therefore, the critical angle is only defined for n₂/n₁≦1.

In some embodiments, protective cover 204, and particularly lens area 206, can be arranged such that light reflected back toward protective cover 204 from photovoltaic material 202 is substantially reflected back to photovoltaic material 202. Such an arrangement can enhance the amount of light that is incident on photovoltaic material 202 and thereby increase the efficiency of photovoltaic system 200.

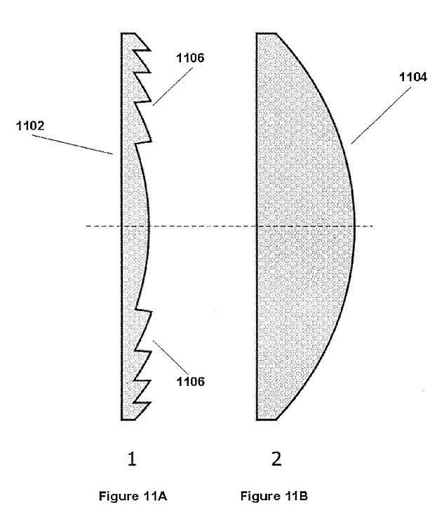

FIGS. 11A and 11B compare features of a Fresnel lens 1102 shown in FIG. 11A with a spherical lens 1104 shown in FIG. 11B. Fresnel lens 1102 can be utilized to reduce the amount of material required, and the space occupied, from that of conventional spherical lens 1104. Fresnel lens 1102 breaks the lens into a set of concentric annular sections 1106 known as Fresnel zones. In the first (and largest) variations of lens 1102, each of zones 1106 can be a different prism. Though lens 1106 might appear to be a single piece of glass or plastic, closer examination reveals that it may be formed of many small pieces. However, some embodiments of lens 1106 may be formed in a single piece of material.

For each of zones 1106, the overall thickness of lens 1102 is decreased, effectively chopping the continuous surface of a standard lens such as lens 1104 into a set of surfaces with the same curvature at each position on the lens as lens 1104, with discontinuities between the sections. This allows a substantial reduction in thickness (and thus weight and volume of material) of lens 1102. Although image quality may be reduced in lens 1102, the image quality is not important in photovoltaic applications where the intensity of light that can be brought onto the surface of a photovoltaic material is the important characteristic.

Fresnel lens 1102 can be utilized in protective cover 204. In some embodiments, protective cover 204 may include Fresnel zones 1106 in lens areas 206. Such Fresnel zones 1106 would serve to direct light incident on lens area 206 towards the center of protective cover 204, and therefore onto the active area of photovoltaic material 202. In some embodiments, Fresnel zones 1106 of lens area 206 have sufficient power that substantially all of the light incident on the top surface of protective cover 204 is incident on the active surface of photovoltaic material 202, and the surface area of the active surface of photovoltaic material 202 is substantially smaller than the surface area of the top surface of protective cover 204.

FIG. 3 illustrates a planar view of an embodiment of photovoltaic system 200 where the enhancement in protective cover 204 includes a display 302. Display 302 can be utilized to display system information such as, for example, a state of charge of a battery, charging current, and power production from photovoltaic system 200. Display information on display 302 can be under the control of a microprocessor and various electronics that are utilized to monitor the power output of photovoltaic material 202. Display 302 can, for example, be a liquid crystal display, light-emitting diode (LED) or organic light-emitting diode (OLED) display, electrophoretic display, or any other display technology. In some embodiments, display 302 is a display that consumes little power.

Protective cover 204, as shown in FIGS. 2 and 3, include an enhancement as part of the cover. In FIG. 2, the enhancement includes a lens area 206, which may include a Fresnel lens or other characteristic that concentrates light toward the underlying photovoltaic material 202. In FIG. 3, the enhancement includes a display 302.

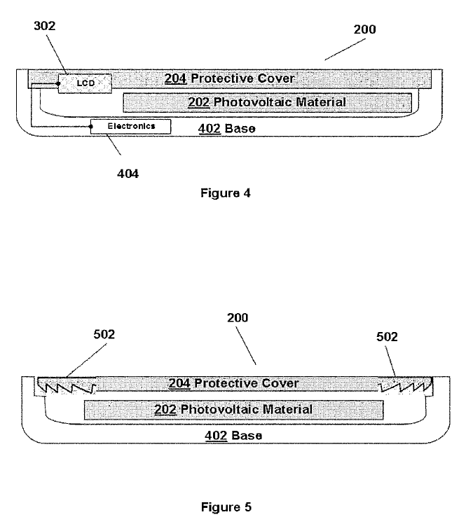

FIG. 4 shows a cross-sectional view of the embodiment of photovoltaic system 200 illustrated in FIG. 3. In the embodiment shown in photovoltaic system 200, photovoltaic material 202 is mounted between protective cover 204 and base 402. Base 402 wraps around so that both protective cover 204 and photovoltaic material 202 are mounted on base 402.

In the embodiment illustrated in FIG. 4, display 302 is embedded in protective cover 204 and located adjacent to photovoltaic material 202 on the underside of protective cover 204. Display 302 is electronically coupled to electronics 404. Electronics 404 can include a microprocessor, memory, and I/O interfaces, or may be dedicated electronics that function to monitor the performance of photovoltaic system 200 and display results on display 302. In some embodiments, display 302 may be completely embedded within the material of protective cover 204, or may be attached to the top or bottom surface of protective cover 204. Further, electronics 404 may be embedded within base 402 or may be mounted adjacent to photovoltaic material 202 in base 402. Also, display 302 may be electronically coupled to electronics 404 with wires embedded within base 402. For example, display 302 may be a color LCD driven by a microprocessor in electronics 404 utilizing a serial interface wire embedded in base 402.

Protective cover 204 as shown in FIG. 2 is transparent to light, for example solar light, and may include anti-reflecting layers in order to increase the amount of light transmitted through protective cover 204. As is discussed above, protective cover 204 may be formed of glass or plastic. Protective cover 204 attaches to photovoltaic system 200, for example by using epoxy to the base 402. In some embodiments, protective cover 204 may withstand natural stress and shocks of devices in general use by consumers. Further, protective cover 204 overlaps photovoltaic material 202 so that the surface area of photovoltaic material 202 is smaller than that of protective cover 204. Photovoltaic material 202 can be any photovoltaic material, including high efficiency materials such as GaAs, single crystal silicon materials, or other thin film or bulk materials.

FIG. 5 illustrates another cross-sectional view of photovoltaic system 200 as illustrated in either of FIGS. 2 or 3. The cross-sectional view may be a view 90° rotated from that shown in FIG. 4 so, with reference to FIG. 3, display 302 is now shown. As shown in FIG. 5, however, the embodiment of photovoltaic system 200 shown in FIG. 5 includes Fresnel type lens areas 502 (i.e., having Fresnel zones 1106) to concentrate light incident on the edge of protective cover 204 onto the surface of photovoltaic material 202. Some embodiments of photovoltaic system 200 may not include a concentrator lens.

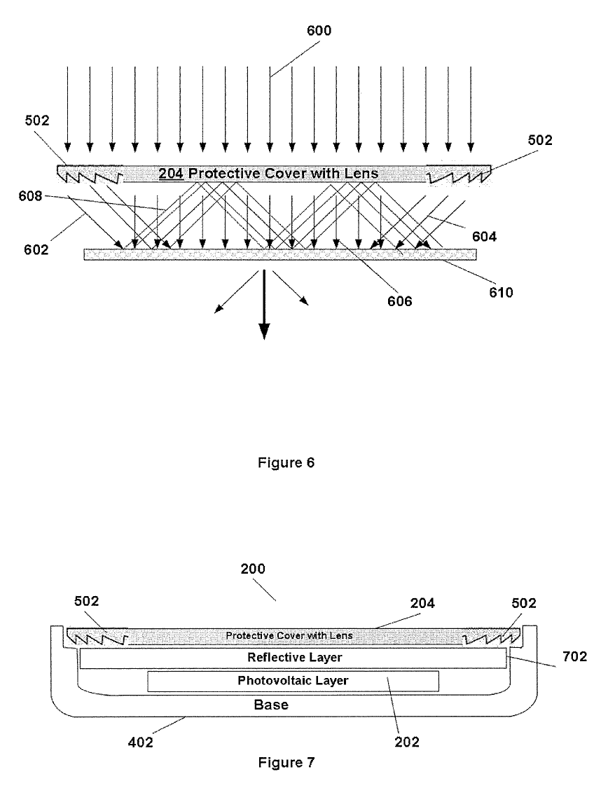

FIG. 6 illustrates the effects of Fresnel lens areas 502 FIG. 6 shows light 600 incident on protective cover 204 refracted by Fresnel lens into rays 602 and 604. As illustrated in FIG. 6, the outer surface of protective cover 204 is smooth, while the inner surface is smooth in appearance or a combination of smooth and serrated to form Fresnel zones 1106, as is further discussed with reference to FIG. 11A. Light incident on the center area of protective cover 204, the area that does not include a Fresnel lens, is not refracted and exits protective cover 204 into rays 606 that are directly incident on photovoltaic material 202. FIG. 6 shows a layer 610 from which reflected rays 608 are reflected back towards protective cover 204. Layer 610 can be a reflective layer 702 as shown in FIG. 7, photovoltaic layer 202, or some other layer. In such fashion, light from the edges of protective cover 204 can be directed onto the active surface of photovoltaic material 202.

As an additional benefit, light rays 602 that are reflected from the surface of photovoltaic material 202 may be internally reflected back onto photovoltaic material 202, allowing more of that light to be absorbed and converted to electrical current by photovoltaic material 202. Using Snell's law as described above, materials for protective cover 204 with an index of refraction that enhances internal reflections may be chosen.

Photovoltaic material 202 is typically most sensitive to specific wavelengths of light. Protective cover 204 may be formed from materials selected to have a high transmittance in the wavelengths where photovoltaic material 202 is most sensitive. A reflective layer 702, such as that shown in FIG. 7, may provide reflective properties at other wavelengths, where photovoltaic material 202 is less sensitive. The reflection of light at particular wavelengths may be exploited to produce cosmetic results to the appearance of photovoltaic system 200. Reflective layer 702 can produce a pleasing cosmetic effect, which may be a single uniform color, may be multiple colors, or may be patterned into a particular pattern or design, depending upon the composition of reflective layer 702.

FIG. 7 illustrates an embodiment of photovoltaic system 200 that includes a reflective layer 702 positioned between protective cover 204 and photovoltaic layer 202. Reflective layer 702 may have a high transmittance in the wavelengths where photovoltaic layer 202 is particularly sensitive and reflect certain wavelengths of light to provide particular coloration or a design to photovoltaic system 200.

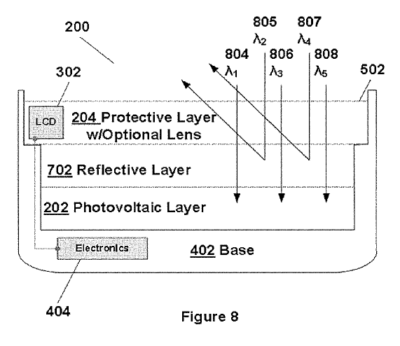

FIG. 8 illustrates operation of reflective layer 702 in photovoltaic system 200. Light of a range of wavelengths, depicted as rays 804 through 808 at wavelengths λ₁ through λ₅, respectively, are incident on protective cover 204. FIG. 8 illustrates an embodiment where light at wavelengths λ₁, λ₃, and λ₅ pass through reflective layer 702 and are directly incident on photovoltaic layer 202 for production of electricity. Reflective layer 702 is arranged such that rays 805 and 807, at wavelengths λ₂ and λ₄, are reflected and therefore exit photovoltaic system 200 through protective layer 204. In some embodiments, the cosmetic effect produced by reflective layer 702 may result without seriously degrading the efficiency of photovoltaic system 200, especially where wavelengths λ₂ and λ₄ are in ranges where photovoltaic material 202 is less sensitive. As a result, photovoltaic device 200 can be provided with a particular coloration when placed under light. Further, reflective layer 702 can be patterned so that different wavelengths are reflected based on location on the surface of reflective layer 702. As a result, reflective layer 702 can be arranged to provide colored patterning to photovoltaic system 200. Patterning may be utilized to display logos or other design features.

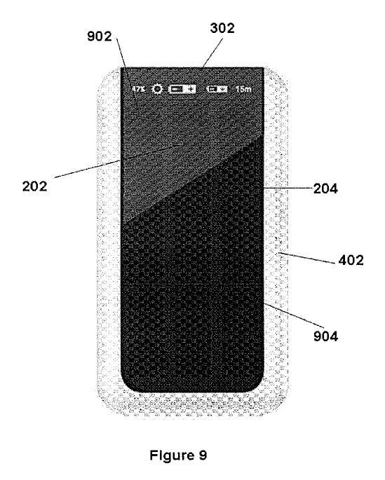

Embodiments of photovoltaic system 200 shown in FIGS. 8 and 9 may include a protective cover with lens areas 502. Due to various materials indices of refraction and the importance of the cosmetic look to the photovoltaic cover, some embodiments may not include lens areas 502. In some embodiments, reflective layer 702 may include an electrophoretic display device coupled to electronics 404. An electrophoretic display reflects light of particular wavelengths depending on charged particles that are suspended in a medium between two plates. Reflective layers 702 may be formed of multiple pixels which reflect light of particular wavelengths when activated by electronics 404.

Electronics 404 may then determine and set the coloration of photovoltaic system 200 and may display various patterns through reflective layer 702 by utilizing a pixel format of the electrophoretic display device. Further, information on the electrophoretic display device may be pixilated so that electronics 404 can cause information to scroll across photovoltaic system 200. Some embodiments of photovoltaic system 200 may not include a reflective layer 702.

FIG. 9 shows a photograph of an embodiment of photovoltaic system 200. As shown in FIG. 9, photovoltaic system 200 is partially lighted in region 902 and partially in shadow in region 904. Display 302 illustrates the charging state of photovoltaic system 200. Base 402 wraps around protective cover 204, which is over photovoltaic layer 202.

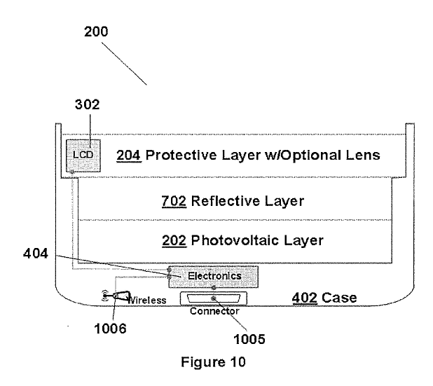

FIG. 10 shows another embodiment of photovoltaic system 200. As shown in FIG. 10, electronics 404 may be coupled to a connector 1005. Further, electronics 404 may also be coupled to a wireless transceiver 1006. Connecter 1005 and wireless transceiver 1006 may be utilized to configure photovoltaic system 200, for example to customize display 302 or reflective layer 702. Connector 1005 may be any of a number of standard connectors, for example a cell phone connector such as the 30-pin connector to the iPhone or other standard connector. Other phone connectors or connectors to other devices may also be utilized. In addition to exchanging information, connector 1005 may be utilized to charge the battery of a device coupled to connector 1005. Wireless transceiver 1006 may be utilized to communicate with a wireless network, for example a Bluetooth network.

As shown in FIG. 10, configuration information specific to an individual user may be input to electronics 404, which may include a microprocessor. Configuration information might contain instructions to generate an alarm (visual or otherwise) if a battery of a device coupled to photovoltaic system 200 is too low for example, or to display the state of solar energy, the status of the coupled device's battery or other information. Wireless transceiver 1006 may allow any computer connected to the wireless network to configure photovoltaic system 200. Physical connector 1005 allows photovoltaic system 200 to physically interface to another computer, which may also configure photovoltaic system 200. Different users may have different configuration requirements. One user may desire all information or alarms to be displayed graphically, another with textual information, still another with a combination of audio and graphical information.

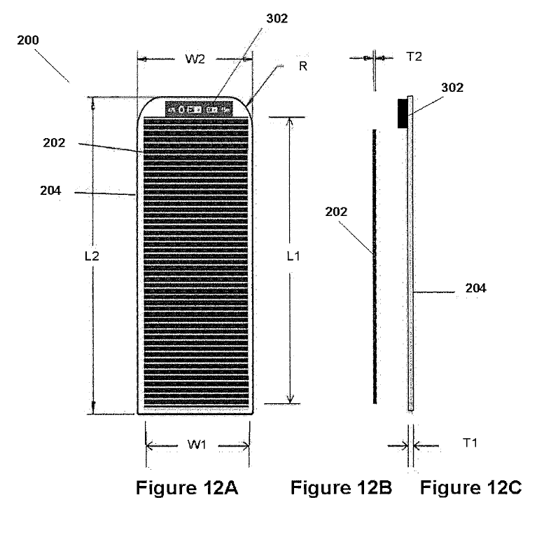

FIGS. 12A, 12B, and 12C illustrate an exemplary embodiment of photovoltaic system 200 consistent with the present invention. In general, photovoltaic system 200 can have any dimensions and can be formed from a large number of materials. As shown in FIG. 12A, protective cover 204 has length L2 and width W2 while photovoltaic material has length L1 and width W1, where L1<L2 and W1<W2. Further, protective cover 204 can have one or more rounded corners characterized by a radius R. As shown in FIG. 12C, protective cover 204 can be, for example, formed from cyclo-olefin polymer with a thickness T1, which may, for example, be about 0.07 inches. Further, some embodiments of photovoltaic system 200 can have L2 of about 4.85 inches W2 of about 2.40 inches. Rounded corners at the top may have a radius of about 0.5 inches. As shown in FIG. 12B, protective cover 204 has a thickness T2 which may be about 0.04 inches.

Photovoltaic material 202 may be formed of P-type mono-crystalline silicon cells and have dimensions L1 of about 4.446 inches, W1 of about 2.16 inches and be about 200 μm in thickness. FIGS. 12A and 12B illustrate that protective cover 204 includes a light emitting diode display 302 that projects back from photovoltaic material 202. Display 302 can show various types of information to the user. As discussed above, in some embodiments protective cover 204 includes lens areas on the edges, which may be formed with Fresnel lens zones as shown in FIG. 11A. In an example embodiment, cover 204 can be an acrylic with index of refraction of about 1.5 and has a length L2 of about 11 cm, and width W2 of about 5 cm, and a thickness T2 of about 1.5 mm. Fresnel zones can be formed with grooves spaced at about 1.3 mm at the edge, the spacing increasing with distance from the edge of protective cover 204, and will provide an effective lens with a focal length of about 12.7 cm. Groove thickness may be about half the thickness of protective cover 204, or in this example about 0.75 mm. A reflective material may be formed around the edge of protective cover 204. Light reflected from the reflective material may be reflected back onto photovoltaic material 202, thereby enhancing the efficiency of photovoltaic system 200.

The embodiments described above are example embodiments of the invention and are not intended to be limiting. One skilled in the art may recognize variations on these embodiments. Those variations are intended to be within the scope of this disclosure. As such, the scope of the invention is limited only by the following claims.

What is claimed is:

1. An apparatus, comprised of:
a base;
a photovoltaic material having an active area mounted to the base; and
a protective cover mounted on the base and covering the photovoltaic material, the protective cover having a surface area larger than that of the active area and including an enhancement.

2. The apparatus of claim 1, wherein the enhancement includes a lens area that concentrates light onto the photovoltaic material.

3. The apparatus according to claim 2, wherein the lens area includes Fresnel zones.

4. The apparatus of claim 2, wherein the lens area includes at least two edges of the protective covering.

5. The apparatus of claim 1, wherein the enhancement includes a display.

6. The apparatus of claim 5, wherein the display includes a liquid crystal display.

7. The apparatus of claim 5, wherein the display includes a light emitting diode or organic light emitting diode.

8. The apparatus of claim 5, wherein the display includes an electrophoretic display.

9. The apparatus of claim 5, wherein the display is located along one edge of the protective cover and the enhancement further includes a lens area located on at least two other edges of the protective covering.

10. The apparatus of claim 5, wherein the display is driven by electronics that monitors power output from the photovoltaic material.

11. The apparatus of claim 1, wherein the protective covering includes an anti-reflective film.

12. The apparatus according to claim 1, wherein the protective covering has a transmittance at wavelengths where the photovoltaic material is sensitive.

13. The apparatus according to claim 1, wherein the protective covering has an index of refraction chosen to enhance internal reflection.

14. The apparatus of claim 1, further including a reflective layer between the photovoltaic material and the protective cover.

15. The apparatus of claim 14, wherein the reflective layer reflects light at one or more wavelengths such that the apparatus has a uniform coloration.

16. The apparatus of claim 14, wherein the reflective layer is patterned so that a graphic display appears on the apparatus.

17. The apparatus of claim 14, wherein the reflective layer includes an electrophoretic display.

18. The apparatus of claim 17, wherein the electrophoretic display can be utilized to display information to a user.

19. The apparatus of claim 17, wherein the electrophoretic display can be utilized to change an appearance of the apparatus.

20. The apparatus according to claim 17, wherein the electrophoretic display is pixilated.

21. A method of providing a photovoltaic system comprised of:
mounting a photovoltaic material in a base;
covering the photovoltaic material with an enhanced cover.

22. The method of claim 21, wherein covering the photovoltaic material includes providing a lens area in the enhanced cover that concentrates light onto the photovoltaic material.

23. The method of claim 22, wherein the lens area includes Fresnel zones.

24. The method of claim 22, wherein the lens area covers at least two edges of the enhanced cover.

25. The method of claim 21, wherein covering the photovoltaic material includes providing a display in the enhanced cover.

26. The method of claim 25, wherein the display includes a liquid crystal display.

27. The method of claim 25, wherein the display includes a light emitting diode or organic light emitting diode.

28. The method of claim 25, wherein the display includes an electrophoretic display.

29. The method of claim 25, wherein the display is located along one edge of the protective cover.

30. The method of claim 25, further including providing electronics that monitors power output from the photovoltaic material and drives the display.

31. The method of claim 21, further including providing an anti-reflective film on the enhanced cover.

32. The method of claim 21, further including forming the enhanced cover from a material that has a transmittance at wavelengths where the photovoltaic material is sensitive.

33. The method of claim 21, further including forming the enhanced cover from a material with an index of refraction chosen to enhance internal reflection.

34. The method of claim 21, further including providing a reflective layer between the photovoltaic material and the enhanced cover.

35. The method of claim 34, wherein the reflective layer reflects light at one or more wavelengths such that a uniform coloration is observed from the enhanced cover.

36. The method of claim 34, wherein the reflective layer is patterned so that a graphic display appears through the enhanced cover.

37. The method of claim 14, wherein the reflective layer includes an electrophoretic display.

38. The method of claim 37, wherein the electrophoretic display can be utilized to display information to a user.

39. The method of claim 37, wherein the electrophoretic display can be utilized to change an appearance of the apparatus.

40. The method of claim 37, wherein the electrophoretic display is pixilated.
